(19) United States
(12) Patent Application Publication
(10) Pub. No.: US 2010/0307585 A1
(43) Pub. Date: Dec. 9, 2010

(54) PHOTOVOLTAIC MODULES WITH FILMS CONTAINING PLASTICISERS HAVING LOW TENDENCY TO CREEP

(75) Inventors: Uwe Keller, Bonn (DE); Martin Steuer, Liederbach (DE); Koichiro Isoue, Okayama (JP)

Correspondence Address: MILLEN, WHITE, ZELANO & BRANIGAN, P.C., 2200 CLARENDON BLVD., SUITE 1400, ARLINGTON, VA, 22201, US

(73) Assignee: KURARAY EUROPE GMBH, Frankfurt (DE)

(21) Appl. No.: 12/794,299

(22) Filed: Jun. 4, 2010

(30) Foreign Application Priority Data
Jun. 5, 2009 (EP) 09162037.6

(51) Int. Cl. H01L 31/0203; C08L 67/07

(52) U.S. Cl. 136/259; 524/539

(57) ABSTRACT

The invention relates to the use of films containing plasticiser and based on polyvinyl acetal with a polyvinyl alcohol content in the polyvinyl acetal of less than 18% by weight and low creep tendency to produce photovoltaic modules.

### TECHNICAL AREA

The invention relates to the production of photovoltaic modules using films based on polyvinyl acetal, containing plasticisers, and having low tendency to creep.

### RELATED ART

Photovoltaic modules consist of a photosensitive semiconductor layer that is provided with a transparent cover to protect it from external influences. Monocrystalline solar cells or polycrystalline, thin semiconductor layers on a substrate may serve as the photosensitive semiconductor layer. Thin-film solar modules consist of a photosensitive semiconductor layer that is deposited, for example by vaporisation, chemical vapour deposition, sputtering, or wet deposition, on a panel which is usually transparent.

Both systems are often laminated between a glass panel and a rigid rear cover panel, made for example from glass or plastics, using a transparent adhesive.

The transparent adhesive must completely enclose the photosensitive semiconductor layer and its electrical connecting wires, it must also be unsusceptible to moisture, and completely free of bubbles after the laminating process.

Films containing plasticisers and based on polyvinyl acetals, such as polyvinyl butyral (PVB), known from composite glass manufacture, may be used as the transparent adhesive. Depending on the module type, the solar cell units are covered or encapsulated with one or more PVB films, and then bonded with the desired covering materials elevated pressure and temperature to create a laminate.

Methods for producing solar modules using PVB films are known for example from DE 40 26 165 C2, DE 42 278 60 A1, DE 29 237 70 C2, DE 35 38 986 C2, U.S. Pat. No. 4,321,418, DE 20 302 045 U1, EP 1617487 A1, or DE 35 389 86 C2. A method whereby moisture absorption and thus also the occurrence of leakage currents may be reduced by using films made from polyvinyl acetals having low polyvinyl alcohol content in combination with low-polarity plasticisers is further disclosed in DE 102007000818.

In this context, a low polyvinyl alcohol content does more than influence the moisture absorption of the film, it is also essential for ensuring that strongly non-polar plasticisers are readily compatible with the polyvinyl acetal. Non-polar plasticisers further enhance moisture reduction or reduced moisture absorption. This is why polyvinyl acetals with polyvinyl alcohol contents less than/equal to 18.0% by weight are used for preference in DE 102007000818.

While this selection is helpful for reducing moisture absorption and leakage currents, the result of polyvinyl alcohol contents as low as this is also to impair the mechanical properties of the intermediate layer with regard to certain features. One such feature is the creep behaviour of the intermediate layer at elevated temperatures, which is significant for the long-term behaviour of photovoltaic modules. Photovoltaic modules are preferably installed under conditions of full direct sunlight, so that temperatures in the range from 80-100° C. may be created in the module due to the high absorption of radiation by the photoactive layers.

If an intermediate layer material tends to creep too readily in this temperature range, in a glass/glass module in which the two glass panels are only connected to one another mechanically via the intermediate layer, for example, the effect of high temperatures may cause the two glass panels to slip with respect to each other over an prolonged period. Moreover, if the module is held in a two-sided retaining device or a device with defined holding points, the module may sag.

Whereas the tendency PVB film to creep with thermal loading is also influenced by the plasticiser content, it is more directly dependent on the properties of the polyvinyl acetal, such as the polyvinyl alcohol content thereof, for example.

Task

The task of the present invention is therefore to provide films based on polyvinyl acetal with a low polyvinyl alcohol content and having a low polyvinyl alcohol content, but which also have a low tendency to creep in a temperature range up to 100° C. for the purpose of manufacturing photovoltaic modules.

It was found that the tendency to creep at elevated temperatures of a film based on polyvinyl acetal and containing plasticisers is influenced primarily by its polyvinyl alcohol content, molar weight, and the degree of crosslinking or acetalisation conditions during production.

### BRIEF DESCRIPTION OF THE INVENTION

Accordingly, the object of the present invention are photovoltaic modules including a laminate consisting of

a) a transparent front cover

b) one or more photosensitive semiconductor layers

c) at least one film based on polyvinyl acetal and containing plasticiser, and

d) a rear cover, wherein the polyvinyl acetal-based film c) containing a plasticiser includes polyvinyl acetal having a polyvinyl alcohol content less than 18% by weight and a creep tendency less than 5 mm after 7 days at a temperature of 100° C., as determined on a laminate with a structure of 3 mm float glass/0.76 mm film c)/3 mm float glass.

When measured according to the method that will be described in greater detail below, the creep tendency of the polyvinyl-acetal based film c) containing plasticiser may be preferably less than 3 mm, particularly less than 2 mm, and most preferably less than 1 mm.

Because of the low polyvinyl alcohol content, plasticisers having low polarity may be used in relatively large quantities, which further improves the films' resistance to moisture without unduly increasing their tendency to creep.

In this context, a sufficiently low polyvinyl alcohol content not only has a direct effect on the moisture absorption capability of the film, it is also an essential prerequisite for ensuring that strongly non-polar plasticisers are readily compatible with the polyvinyl acetal, which in turn favours further moisture reduction by the selection of such a plasticiser.

For this reason, polyvinyl acetals having less than 18% by weight polyvinyl alcohol contents are selected for films that are to be used according to the invention. The polyvinyl acetals used according to the invention preferably have a polyvinyl alcohol content less than 16% by weight, particularly preferably less than 15% by weight, and especially less than 13% by weight. The polyvinyl alcohol component should not be less than 10% by weight.

In a first variant of the invention, the films are made using polyvinyl acetals having a weight average molecular weight Mw greater than 110,000 g/mol, preferably Mw greater than 120,000 g/mol, and/or having a solution viscosity greater than 80 mPas, preferably greater than 90 mPas. As indicated in the examples, the Mw molecular weight and the solution viscosity are measured by gel permeation chromatography (GPC) and in a 5% solution of the polyvinyl acetals in ethanol.

In order to avoid impairing the extrudability of the polyvinyl acetals, the Mw molecular weight should not be greater than 500,000 g/mol, and/or the solution viscosity should not be greater than 300 mPas.

Macroscopically, both the Mw molecular weight and the solution viscosity represent specific values for the polyvinyl acetal used. Therefore, mixtures of several polyvinyl acetals, whose respective Mw molecular weights and solution viscosities may be above and below the limit values indicated, may also be used. The process of mixing a plurality of polyvinyl acetals to obtain a mixture having the stated lower limits for molecular weight and solution viscosity is known to one skilled in the art.

The increased molecular weight and solution viscosity may be achieved by using corresponding polyvinyl alcohols in the production of the polyvinyl acetals. The polyvinyl alcohols used to produce the polyvinyl acetals preferably have a solution viscosity of more than 35 mPas, measured in a 4% aqueous solution. In the context of the present invention, the polyvinyl alcohols may be used pure or as a mixture of polyvinyl alcohols having differing degrees of polymerisation or hydrolysis. If mixtures of polyvinyl alcohols are used, the solution viscosity thereof according to the invention is above 35 mPas.

Films that contain polyvinyl acetals having the specifications defined for Mw molecular weight and solution viscosity are also practically equivalent to those based on polyvinyl acetal having a Mw molecular weight of <110,000 g/mol and a solution viscosity of <80 mPas in respect of other desirable properties, such as lower moisture absorption, reduction of leakage currents, or increased optical transparency.

The polyvinyl acetals required for producing the films used according to the invention are obtained by the known methods, by reacting polyvinyl alcohols having a corresponding molar weight and residual acetate content with one or more aldehydes.

In the context of the present invention, either copolymers of vinyl alcohol and vinyl acetate or terpolymers from hydrolysed vinyl acetate/ethylene copolymers may be used as the polyvinyl alcohol. These compounds are normally more than 98% hydrolysed and contain 1 to 10 ethylene based units by weight (for example of the type “Exceval” by Kuraray Europe GmbH).

Also in the context of the present invention, hydrolysed copolymers of vinyl acetate and at least one other ethylene unsaturated monomer may be used as the polyvinyl alcohol.

It is possible to carry out the acetalisation with aldehydes having 2 to 10 carbon atoms, preferably with acetaldehyde, butyraldehyde, or valeraldehyde.

In another, second variant of the invention, the polyvinyl acetals used according to the invention have increased molecular weight and greater solution viscosity as a result of crosslinking via carboxyl groups, or due to polyaldehydes, glutardialdehyde or glyoxylic acid.

Crosslinked polyvinyl acetals may be obtained for example by intramolecular crosslinking of carboxyl group-substituted polyvinyl acetals. These may be produced for example by coacetalisation of polyvinyl alcohols with polyaldehydes, glutardialdehyde or glyoxylic acid. It is particularly preferred if the polyvinyl acetals obtained thereby satisfy the lower limits for Mw molecular weight and solution viscosity described in the preceding.

Suitable crosslinking options for polyvinyl acetals are described for example in EP 1527107 B1 and WO 2004/063231 A1 (thermal autocrosslinking of carboxyl group-containing polyvinyl acetals), EP 1606325 A1 (polyvinyl acetals crosslinked with polyaldehydes), EP 1622946 A1 (polyvinyl acetals crosslinked with glutardialdehyde), and WO 03/020776 A1 (polyvinyl acetals crosslinked with glyoxylic acid). The disclosures of these patent applications are included in their entirety by this reference. Crosslinking of polyvinyl acetal is observable macroscopically via an increased molecular weight and viscosity of an ethanolic solution.

In a third variant of the invention, the properties of the polyvinyl acetals used according to the invention are adjusted via the acetalisation conditions thereof when they are manufactured. The conventional manner for producing polyvinyl acetals is to prepare a mixture of polyvinyl alcohol and aldehyde or of polyvinyl alcohol and an acid such as HCl, to which an acid or aldehyde is added at a temperature of 0 to 20° C., so that the polyvinyl acetal is precipitated (precipitation phase). The precipitation phase begins with the addition of the last component (acid or aldehyde) and usually lasts between 60 and 360 minutes, preferably between 60 and 240 minutes. The precipitation phase ends when heating to the final temperature starts.

The beginning of heating is the start of the heating phase. Subsequently, the reaction is completed at a final temperature of 30 to 80° C., after which the reaction mixture is cooled, and the polyvinyl acetal is separated and processed. The heating phase ends with the start of cooling, and usually lasts between 30 and 300 minutes.

Polyvinyl acetals that are particularly suitable for use in producing the photovoltaic modules according to the invention are such that have been manufactured by methods having the following steps:
preparation of an aqueous solution of polyvinyl alcohol and at least one aldehyde
addition of an acid, resulting in precipitation of the polyvinyl acetal at low temperature (precipitation phase), wherein the precipitation phase preferably lasts between 60 and 240 minutes

Alternatively, the precipitation phase may also be performed as follows:
preparation of an aqueous solution of polyvinyl alcohol and acid
addition of at least one aldehyde, resulting in precipitation of the polyvinyl acetal at low temperature (precipitation phase), wherein the precipitation phase lasts between 60 and 360 minutes, preferably between 60 and 240 minutes.

In the two variants, the acid and aldehyde may be added all at once or incrementally.

In both variants, the following process step is carried out afterwards (heating phase):
heating of the reaction mixture to an elevated temperature
reheating at an elevated temperature, wherein the entire heating phase lasts between 30 and 300 minutes.

Polyvinyl acetals that are suitable for the present invention are produced with a precipitation phase that is significantly longer than the heating phase, as is described for example in DE 2838025, U.S. Pat. No. 5,187,217, EP 1384731, WO 2004/005358, EP 0211819 JP 01318009 or WO 2005 070669. The disclosures of these patent applications are included in their entirety by this reference. It is particularly preferred if the polyvinyl acetals obtained thereby satisfy the lower limits for Mw molecular weight and solution viscosity described in the preceding.

In a fourth variant of the invention, polyvinyl acetals that are particularly suitable for the present invention are obtained by combining a manufacturing process including a long precipitation phase, as described for the third variant, with a crosslinking reaction, for example by thermal autocrosslinking of polyvinyl acetals that contain carboxyl groups, or by crosslinking the polyvinyl acetal with polyaldehydes, glutardialdehyde, or glyoxylic acid. The crosslinking reaction may take place while the polyvinyl acetal is being produced (that is to say during the reaction between polyvinyl alcohol and aldehyde) by simultaneously adding the aldehyde and the crosslinking substance, or else in a separate reaction step such as adding the crosslinking substance to the extrusion of the film containing the plasticiser. It is particularly preferred if the polyvinyl acetals obtained thereby satisfy the lower limits for Mw molecular weight and solution viscosity described in the preceding.

Regardless of the production method and any crosslinking, the polyvinyl acetals used according to the invention also include units resulting from vinyl acetate and vinyl alcohol, and possibly other comonomers as well, in addition to the acetal units.

The polyvinyl acetate component of the polyvinyl acetals used in accordance with the invention is preferably less than 14% by weight, particularly preferably less than 10% by weight, or less than 5% by weight and particularly less than 2% by weight respectively. The degree of acetalisation may be calculated arithmetically from the polyvinyl alcohol component and the residual acetate content.

The edge areas of the films used according to the invention preferably have moisture or water contents not exceeding 2.3% by weight, not exceeding 2.0% by weight, not exceeding 1.8% by weight, and particularly preferably not exceeding 1.5% by weight even in humid conditions. Photovoltaic modules equipped with films of this kind may be covered as far as very close to the film edge with photosensitive semiconductor layers, and thus offer more surface area and greater current efficiency.

The films used according to the invention preferably have a specific resistance of at least 1E+11 ohm*cm, particularly at least 5E+11 ohm*cm, especially 1E+12 ohm*cm, particularly preferably 5E+12 ohm*cm, especially preferably 1E+13, more preferably still 5E+13 ohm*cm, and most preferably 1E+14 ohm*cm in ambient humidity of 85% rF at 23° C.

The moisture absorption and specific resistance of films based on polyvinyl acetal and containing plasticisers are also affected by the proportion and polarity, or the softening effect, of the plasticiser used. In this way, moisture absorption and specific resistance may also be adjusted simply via the plasticiser.

The films preferably have a plasticiser content in the range from 18 to 32 by weight, preferably in the range from 20 to 30% by weight, particularly in the range from 22 to 28% by weight, and especially in the range from 24 to 27% by weight. Films and thus photovoltaic modules according to the invention may contain one or more plasticisers.

Particularly suitable for the purposes of the invention are plasticisers whose polarity, as expressed in the formula 100×O/(C+H), is less than/equal to 9.4, where O, C and H stand for the number of oxygen, carbon, and hydrogen atoms in the respective molecule. The following table lists plasticisers that are usable according to the invention, together with their polarity values according to the formula 100×O/(C+H).

| Name | Abbreviation | 100 × O/(C + H) |
|---|---|---|
| Di-2-ethylhexyl sebacate | (DOS) | 5.3 |
| 1,2 Cyclohexane dicarboxylic acid | (DINCH) | 5.4 |
| diisononyl ester | | |
| Di-2-ethylhexyl adipate | (DOA) | 6.3 |
| Di-2-ethylhexyl phthalate | (DOP) | 6.5 |
| Dihexyl adipate | (DHA) | 7.7 |
| Dibutyl sebacate | (DBS) | 7.7 |
| Di-2-butoxyethyl sebacate | (DBES) | 9.4 |
| Triethylene glycol-bis-2-ethylhexanoate | (3G8) | 9.4 |

The following plasticisers are less suitable:

| Name | Abbreviation | 100 × O/(C + H) |
|---|---|---|
| Triethylene glycol-bis-n-heptanoate | 3G7 | 10.3 |
| Tetraethylene glycol-bis-n-heptanoate | 4G7 | 10.9 |
| Di-2-butoxyethyl adipate | DBEA | 11.5 |
| Di-2-butoxyethoxyethyl adipate | DBEEA | 12.5 |

The adhesion of polyvinyl acetal films to glass is conventionally adjusted via the addition of adhesion regulators such as the alkali and/or alkaline earth salts of organic acids disclosed in WO 03/033583 A1. Potassium acetate and/or magnesium acetate have proven to be particularly suitable. In addition, polyvinyl acetals obtained by the production process often contain alkali and/or alkaline earth salts of inorganic salts, such as sodium chloride, for example.

Since salts also affect specific resistance, the use of films based on plasticiser-containing polyvinyl acetals having less than 50 ppm, particularly preferably less than 30 ppm, and especially less than 20 ppm metal ions is advantageous. This may be achieved with appropriate methods for washing the polyvinyl acetal and the use of highly effective anti-adhesive substances, for example magnesium, calcium, and/or zinc salts of organic acids such as are known to one skilled in the art.

In addition, ionic mobility, which may depend on the water content of the film, and thus also specific resistance, may be influenced by the addition of pyrogenic silica. The plasticiser-containing films based on polyvinyl acetal preferably contain 0.001 to 15% by weight, particularly 0.5 to 5% by weight pyrogenic SiO₂.

The general method of production and composition of films based on polyvinyl acetals is described for example in EP 185 863 B1, EP 1 118 258 B1, WO 02/102591 A1 EP 1 118 258 B1 or EP 387 148 B1.

The photovoltaic modules are laminated by fusing the films in such manner as to ensure that the photosensitive semiconductor layer is embedded in the films without bubbles or streaks.

In a variant of the photovoltaic modules according to the invention, the photosensitive semiconductor layers are applied to cover d) (for example by vaporisation, chemical vapour deposition, sputtering, or wet deposition) and stuck to cover a) via a film c).

Alternatively, the photosensitive semiconductor layers are embedded between two films c), and stuck to both covers a) and d).

The thickness of the films based on polyvinyl acetal and containing plasticiser is between 0.2 and 2.5 mm.

During the lamination process, films that are used according to the invention completely fill the cavities on the photosensitive semiconductor layers and their electrical connectors.

The transparent front cover is usually made from glass or PMMA. The rear cover of the photovoltaic module according to the invention may consist of glass, plastic or metal, or composites thereof, wherein at least one of the substrates may be transparent. It is also possible to construct one or both covers as a composite glass panel (that is to say as a laminate of at least two glass plates and at least one PVB film), or as an insulating glass panel having a gas-filled interspace. Of course, it is also possible to combine these constructions.

The photosensitive semiconductor layers used in the modules are not required to possess any special properties. Monocrystalline, polycrystalline, or amorphous systems may be used.

In thin-film solar modules, the photosensitive semiconductor layer is applied directly to a substrate. Encapsulation is not possible here. Accordingly, the layered product, consisting of a substrate (for example the rear cover) is bonded with the photosensitive semiconductor layer and the transparent front cover by at least one interposed polyvinyl acetal-based, plasticiser-containing film c), and joined adhesively thereby at elevated temperature. Alternatively, the photosensitive semiconductor layer may be applied to the transparent front cover as a substrate, and adhered to the rear cover by at least one interposed polyvinyl acetal-based, plasticiser-containing film c).

The methods familiar to one skilled in the art, with and without prior preparation of a preliminary composite, may be used for laminating the layered product obtained in this way.

Autoclaving processes are conducted for about 2 hours under elevated pressures of about 10 to 15 bar, and at temperatures from 130 to 145° C. Vacuum bag or vacuum ring methods, such as are described in EP 1 235 683 31, for example, function at about 200 mbar and 130 to 145° C.

The photovoltaic modules according to the invention are preferably produced using vacuum laminators. Vacuum laminators include a heatable, evacuatable chamber in which composite glass panels are able to be laminated within 30-60 minutes. Partial vacuums from 0.01 to 300 mbar and temperatures from 100 to 200° C., particularly 130-160° C. have proven advantageous in practice.

Alternatively, a layered product created as described above may be pressed between at least one pair of rollers at a temperature of 60 to 150° C. to form a module according to the invention. Systems of such kind for producing composite glass panels are known, and are normally equipped with at least one heating tunnel before or after the first pressing plant in systems with two pressing plants.

A further object of the invention is the use of plasticiser-containing, polyvinyl acetal-based film c) with a polyvinyl alcohol proportion of less than 18% by weight of the polyvinyl acetal, and a creep tendency of less than 5 mm after 7 days at a temperature of 100° C., as determined on a laminate having a construction of 3 mm float glass/0.76 mm film c)/3 mm float glass, to produce photovoltaic modules. The photovoltaic modules preferably include a laminate consisting of
a) a transparent front cover
b) one or more photosensitive semiconductor layers
c) at least one polyvinyl acetal-based film containing plasticiser, and
d) a rear cover

Films c) in the preferred embodiments described may be used to produce the photovoltaic modules.

Photovoltaic modules according to the invention may be used as building façade elements, roof surfaces, conservatory cover panels, soundproofing walls, balcony or balustrade elements, or as window area elements.

Measurement Methods:

The glass transition temperature of the film is determined by dynamic differential scanning calorimetry (DSC) in accordance with DIN 53765 using a heating rate of 10K/min in a temperature interval from −50° C.-150° C. In the heating program, a first heat ramp is followed by a cooling ramp, and then a second heat ramp. The position of the glass transition temperature is determined on the measurement curve associated with the second heat ramp in accordance with DIN 51007. The DIN average (Tg DIN) is defined as the intersection of a horizontal line at half the step height with the measurement curve. The step height is defined by the vertical distance between the two intersections of the average tangent with the base line of the measurement curve before and after glass transition.

The flow behaviour of the film is determined as the melt index (mass flow: MFR) in accordance with ISO 1133 on an appropriate device, such as the model MI2 produced by Göttfert. The MFR value is indicated in grams per 10 minutes (g/10 min) at the corresponding temperatures, for example 100° C. and 140° C., with the 2 mm nozzle and a weight load of 21.6 kg.

The specific contact resistance of the film is measured in Ohm*cm in accordance with DIN IEC 60093 at a defined temperature and ambient humidity (23° C. and 85% RH) after the film has been exposed to these conditions for at least 24 h. To carry out the measurement, a type 302 132 plate electrode produced by Fetronic GmbH and a ISO-Digi 5 kV resistance measuring device produced by Amprobe are used. The test voltage was 2.5 kV, the wait time after the test voltage was applied until the measurement was recorded was 60 sec. To ensure adequate contact between the flat plates of the measurement electrode and the film, the surface roughness R_{z} thereof as defined in DIN EN ISO 4287 should not be greater than 10 μm, that is to say, the original surface of the PVB film may have to be smoothed by thermal recoining before the resistance measurement is taken.

The polyvinyl alcohol and polyvinyl alcohol acetate content of the polyvinyl acetals was determined in accordance with ASTM D 1396-92.

The metal ion content analysis was performed by atomic absorption spectroscopy (AAS).

The Mw molecular weight (=weight average) of the polyvinyl acetals was determined by gel permeation chromatography (GPC) in glacial acetic acid with the aid of RI detectors. The detectors were calibrated using PVB calibration standards, the absolute values of which were determined by static light scattering.

The solution viscosity of the polyvinyl acetals was measured in accordance with DIN 53015 at 20° C. in a mixture of 95 parts ethanol to 5 parts water. The solid content constituted 5% by weight of the viscosity solution.

The solution viscosity of the polyvinyl alcohols was measured in accordance with DIN 53015, in water at 20° C. The constituted 4% by weight of the viscosity solution.

The water and moisture content of the films is determined in percent by weight by the Karl-Fischer method. In order to simulate moisture uptake behaviour in humid conditions, the film is stored at 23° C. and 85% RH for 24 h beforehand. This method may be performed both with the unlaminated film and with a laminated photovoltaic module depending on the distance from the edge of the film.

Test of Creep Tendency

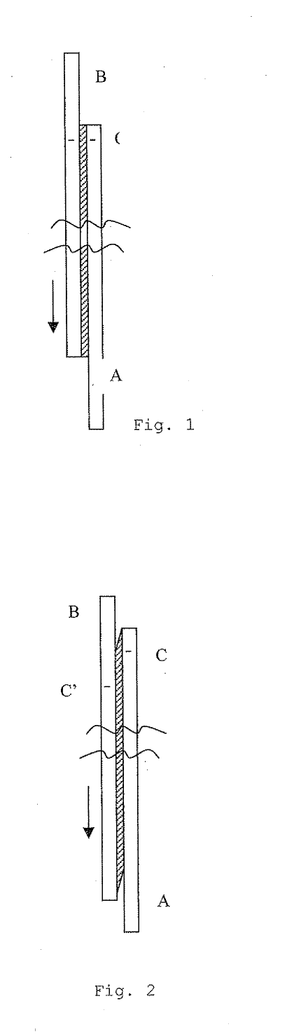

The tendency of the films to creep is determined on test laminates that are produced from two 3 mm thick panes of float glass having edge dimensions of 150×300 mm with a film having a thickness of 0.76 mm laminated therebetween in such manner that the two glass panes are offset lengthwise by 2 cm with respect to each other (A/B in FIGS. 1 and 2). The film that is to be tested for its tendency to creep is conditioned in an atmosphere of 23° C./23% RH overnight before the laminate is made.

### BRIEF DESCRIPTION OF THE DRAWINGS

The two protruding glass sections are not covered with film, that is to say the intermediate layer in the laminate is only 28 cm long. The test laminates are marked on exactly opposite sides with diagonal lines using a marker, and these will later be used to measure the offset caused by slippage more easily later. (C in FIG. 1) The test laminates are arranged and secured vertically in a heating cabinet at 100° C. in such manner that the front glass panel, which is not touching the ground (B in FIGS. 1 and 2) is able to slip down freely under its own weight, that is to say it is only held in place by, and is only in contact with, the intermediate film layer, such that the result is not distorted by the effects of friction. After 7 days (one week), the test laminates are examined for any offset by measuring the distance between the two marks with a straight edge. (C and C′ in FIG. 2).

### EXAMPLES

Films having a thickness of 0.76 mm were prepared from mixtures having the compositions listed in the following tables, and were examined as laminates between 2 panels of 3 mm thick white glass (Optiwhite) with respect to their suitability for use in producing photovoltaic modules, that is to say with regard their creep tendency and electrical contact resistance.

It was revealed that the films used according to the invention are well adapted for processing to form photovoltaic modules, because they encapsulate the solar cells fully. At the same time, their low creep values (=slippage) at 100° C. indicate low flowability at this temperature, demonstrating that the modules thus obtained are stable when exposed to environmental and mechanical influences.

Films exhibiting the flowability characteristics described are particularly suitable for use in producing photovoltaic modules because they demonstrate no slippage of the cover layers relative to the adhesive film, but are readily workable.

The following abbreviations are used:

DINCH 1,2-Cyclohexane dicarboxylic diisononyl ester

3G8 Triethylene glycol-bis-2-ethylhexanoate

PVB Polyvinyl butyral with the PVA content indicated

### Comparison Example 1

100 parts by weight of the polyvinyl alcohol Mowiol 28-99 (commercial product by Kuraray Europe GmbH) were dissolved in 1075 parts by weight water while heating to 90° C. 56.8 parts by weight n-Butyraldehyde were added at a temperature of 40° C., and 75 parts by weight of 20% hydrochloric acid were added at a temperature of 12° C. within 6 minutes while stirring, following which the polyvinylbutyral (PVB) was precipitated. The mixture was then stirred and maintained at a tempature of 12° C. for 15 minutes, then heated to 69° C. within 80 minutes and maintained at this temperature for 120 minutes. After cooling to room temperature, the PVB was separated off, washed in neutral water, and dried. A PVB having a polyvinyl alcohol content of 20.2% by weight and a polyvinyl acetate content of 1.5% by weight was obtained.

290 g of the PVB obtained thus and 100 g 3G8 plasticiser and 10 g DBEA plasticiser were mixed in a laboratory mixer (manufactured by: Brabender, model 826801). The mixture was extruded to form a flat film with a thickness of 0.8 mm. Extrusion was carried out in a twin screw extruder with counter-rotating screws (manufacturer: Haake, System Rhecord 90) and equipped with a melt pump and a sheet die. The cylinder temperature of the extruder was 220° C., the die temperature was 150° C.

### Comparison Example 2

63.9 parts by weight n-Butyraldehyde were used for polymer synthesis. 370 g PVB and 130 g DINCH plasticiser were used to produce the film. The subsequent process was the same as for comparison example 1.

### Comparison Examples 3-4

66.3 and 68.4 parts by weight n-Butyraldehyde were used for polymer synthesis. The subsequent process was the same as for comparison example 2.

### Examples 1, 2 and 3

For polymer synthesis, 100 parts by weight of Mowiol 56-98 polyvinyl alcohol (commercial product manufactured by Kuraray Europe GmbH), 1333 parts by weight water, and 67.9, 68.4 and 69 parts by weight n-Butyraldehyde were used. The subsequent process was the same as for comparison example 2.

### Examples 4 and 5

For polymer synthesis, 100 parts by weight of Kuraray Poval 624 polyvinyl alcohol (commercial product manufactured by Kuraray Europe GmbH), 1333 parts by weight water, 100 parts by weight 20% hydrochloric acid, and 70 and 73 parts by weight respectively n-Butyraldehyde were used. The subsequent process was the same as for comparison example 2.

### Comparison Example 5

The film was produced using a mixture of 333 g PVB from comparison example 4 and 37 g PVB from example 2. The subsequent process was the same as for comparison example 2.

### Example 6

The film was produced using a mixture of 259 g PVB from comparison example 4 and 111 g PVB from example 2. The subsequent process was the same as for comparison example 2.

### Example 7

The film was produced using a mixture of 185 g PVB from comparison example 4 and 185 g PVB from example 2. The subsequent process was the same as for comparison example 2.

### Example 8

The film was produced using a mixture of 185 g PVB from, comparison example 4 and 185 g PVB from example 3. The subsequent process was the same as for comparison example 2.

### Examples 9-12

For polymer synthesis, 68.4 parts by weight n-Butyraldehyde and additionally 0.02, 0.04, 0.06 and 0.08 parts by weight glutaraldehyde were used. The subsequent process was the same as for comparison example 2.

### Examples 13-14

For polymer synthesis, 100 parts by weight Mowiol 30-92 polyvinyl alcohol, (commercial product manufactured by Kuraray, Europe GmbH), 1075 parts by weight water, 67.1 parts by weight n-Butyraldehyde, 100 parts by weight 20% hydrochloric acid, and 0.04 and 0.08 parts by weight respectively of glutaraldehyde were used. The subsequent process was the same as for comparison example 2.

### Example 15

100 parts by weight Mowiol 28-99 polyvinyl alcohol, (commercial product manufactured by Kuraray Europe GmbH) were dissolved in 1075 parts by weight water while heating to 90° C. 68.4 parts by weight n-Butyraldehyde were added at a temperature of 40° C., and then 15 parts by weight of 20% hydrochloric acid were added at a temperature of 12° C. within 15 minutes, after which the polyvinylbutyral (PVB) was precipitated. The mixture was then maintained at 12° C. while stirring for 60 minutes. Then, a further 50 parts by weight 20% hydrochloric acid were added within 40 minutes. After this, the mixture was maintained at 12° C. for a further 15 minutes, after which it was heated to 69° C. within 80 minutes, and maintained at this temperature for 120 minutes. The subsequent process was the same as for comparison example 2.

### Example 16-17

The period between the additions of the first and second quantities of acid was 120 and 180 minutes respectively. The subsequent process was the same as for example 15.

### Example 18

100 parts by weight Mowiol 28-99 polyvinyl alcohol (commercial product manufactured by Kuraray Europe GmbH) were dissolved in 1075 parts by weight water while heating to 90° C. At a temperature of 40° C., 68.4 parts by weight n-Butyraldehyde and 0.03 parts by weight glutaraldehyde were added. At a temperature of 12° C., 75 parts by weight 20% hydrochloric acid were added within 6 minutes while stirring, after which the polyvinylbutyral (PVB) was precipitated. The mixture was then maintained at 12° C. for a further 120 minutes while stirring, then heated to 69° C. within 80 minutes, and maintained at this temperature for 120 minutes. The subsequent process was the same as for comparison example 2.

### Example 19

100 parts by weight Mowiol 28-99 polyvinyl alcohol (commercial product manufactured by Kuraray Europe GmbH) were dissolved in 1075 parts by weight water while heating to 90° C. At a temperature of 40° C., 68.4 parts by weight n-Butyraldehyde and 0.03 parts by weight glutaraldehyde were added. At a temperature of 12° C., 15 parts by weight 20% hydrochloric acid were added within 15 minutes while stirring, after which the polyvinylbutyral (PVB) was precipitated. The mixture was then maintained at 12° C. for a further 120 minutes while stirring. Then, a further 50 parts by weight 20% hydrochloric acid were added within 40 minutes. The mixture was subsequently maintained at 12° C. for a further 15 minutes while stirring, then heated to 69° C. within 80 minutes, and maintained at this temperature for 120 minutes. The subsequent process was the same as for comparison example 2.

### Examples 20-21

100 parts by weight Mowiol 30-92 polyvinyl alcohol (commercial product manufactured by Kuraray Europe GmbH) were dissolved in 1075 parts by weight water while heating to 90° C. At a temperature of 40° C., 67.1 parts by weight n-Butyraldehyde and 0.06 parts by weight glutaraldehyde were added. At a temperature of 12° C., 100 parts by weight 20% hydrochloric acid were added within 6 minutes while stirring, after which the polyvinylbutyral (PVB) was precipitated. The mixture was then maintained at 12° C. for a further 60 or 120 minutes respectively while stirring, and then heated to 69° C. within 80 minutes and maintained at this temperature for 120 minutes. The subsequent process was the same as for comparison example 2.

TABLE 1

| | Example | | | | |
|---|---|---|---|---|---|
| | VG 1 | VG 2 | VG 3 | VG 4 | VG 5 |
| PVB | | | | | |
| Viscosity PVA 4% (mPa · s) | 27.06 | 27.06 | 27.06 | 27.06 | — |
| Precipitation phase [min] | 21 | 21 | 21 | 21 | — |
| Heating phase [min] | 200 | 200 | 200 | 200 | — |
| Polyvinyl alcohol content | 20.2 | 16.0 | 15.0 | 14.3 | 14.4 |
| [w %] | | | | | |
| Polyvinyl acetate content | 1.5 | 0.9 | 1.1 | 0.9 | 1.0 |
| [w %] | | | | | |
| Butyral content [w %] | 78.3 | 83.1 | 83.9 | 84.8 | 84.6 |
| Polyvinyl alcohol content | 29.1 | 23.5 | 22.2 | 21.2 | 21.4 |
| [mol %] | | | | | |
| Polyvinyl acetate content | 1.1 | 0.7 | 0.8 | 0.7 | 0.8 |
| [mol %] | | | | | |
| Butyral content [mol %] | 69.8 | 75.8 | 77.0 | 78.1 | 77.9 |
| Viscosity PVB 5% (mPa · s) | 81.4 | 68.2 | 70 | 72.9 | 90.1 |
| Film | | | | | |
| Plasticiser | 3G8/DBEA | DINCH | DINCH | DINCH | DINCH |
| | (10:1) | | | | |
| Plasticiser [w %] | 27.5 | 26.0 | 26.0 | 26.0 | 26.0 |
| Tg, Midpoint DIN [° C.] | 18.8 | 24.99 | 23.47 | 21.73 | — |
| Mw, PVB [g/mol] | 103000 | 103800 | 103000 | 101950 | 106000 |
| MFR 100° C./21.6 kg | 165 | 397 | 465 | 378 | 351 |
| [mg/10 min.] | | | | | |
| Electrical contact | 1.20E+11 | 7.20E+13 | 2.80E+13 | 4.30E+13 | 3.00E+13 |
| resistance in Ohm * cm | | | | | |
| Water content according to | 3.09 | 1.87 | 1.73 | 1.87 | 1.67 |
| Karl-Fischer method in | | | | | |
| %/weight % | | | | | |
| Slippage in mm | 0 | 8.5 | 9 | 7 | 5 |

TABLE 2

| | Example | | | | | |
|---|---|---|---|---|---|---|
| | B1 | B2 | B3 | B4 | B5 | 56 |
| PVB | | | | | | |
| Viscosity PVA 4% (mpa · s) | 56.36 | 56.36 | 56.36 | 55.92 | 55.92 | — |
| Precipitation phase [min] | 21 | 21 | 21 | 21 | 21 | — |
| Heating phase [min] | 200 | 200 | 200 | 200 | 200 | — |
| Polyvinyl alcohol content | 15.6 | 15.0 | 14.1 | 13.5 | 12.7 | 14.5 |
| [w %] | | | | | | |
| Polyvinyl acetate content | 2.0 | 2.1 | 1.9 | 5.4 | 5.7 | 1.3 |
| [w %] | | | | | | |
| Butyral content [w %] | 82.4 | 83.0 | 84.0 | 81.1 | 81.6 | 84.2 |
| Polyvinyl alcohol content | 23.0 | 22.2 | 21.0 | 20.3 | 19.2 | 21.5 |
| [mol %] | | | | | | |
| Polyvinyl acetate content | 1.5 | 1.6 | 1.5 | 4.1 | 4.4 | 1.0 |
| [mol %] | | | | | | |
| Butyral content [mol %] | 75.5 | 76.2 | 77.6 | 75.6 | 76.4 | 77.5 |
| Viscosity PVB 5% (mPa · s) | 179.8 | 177.3 | 177.8 | 1.95.8 | 205.9 | 105.5 |
| Film | | | | | | |
| Plasticiser | DINCH | DINCH | DINCH | DINCH | DINCH | DINCH |
| Plasticiser [w %] | 26.0 | 26.0 | 26 | 26 | 26 | 26.0 |
| Tg, Midpoint DIN [° C.] | 23.81 | 24.16 | — | — | — | — |
| Mw, PVB [g/mol] | 143300 | 144300 | 143775 | 150800 | 150200 | 113500 |
| MFR 100° C./21.6 kg | 88 | 83 | 97 | 84 | 97 | 263 |
| [mg/10 min.] | | | | | | |
| Electrical contact | 4.70E+13 | 3.50E+13 | 7E+13 | 1.10E+14 | 9.40E+13 | 4.10E+13 |
| resistance in Ohm * cm | | | | | | |
| Water content according to | 1.79 | 1.76 | 1.7 | 1.61 | 1.55 | 1.69 |
| Karl-Fischer method in | | | | | | |
| %/weight % | | | | | | |
| Slippage in mm | 1 | 1 | 0 | 1 | 1 | 2 |

TABLE 3

| | Example | | | | | |
|---|---|---|---|---|---|---|
| | B7 | B8 | B9 | B10 | B11 | B12 |
| PVB | — | — | | | | |
| Viscosity PVA 4% (mPa · s) | — | — | 26.8 | 27.06 | 27.06 | 27.06 |
| Precipitation phase [min] | — | — | 21 | 21 | 21 | 21 |
| Heating phase [min] | — | — | 200 | 200 | 200 | 200 |
| Polyvinyl alcohol content | 14.7 | 14.2 | 14.5 | 14.5 | 14.2 | 14.4 |
| [w %] | | | | | | |
| Polyvinyl acetate content | 1.5 | 1.4 | 1.2 | 0.9 | 1.0 | 0.9 |
| [w %] | | | | | | |
| Butyral content [w %] | 83.8 | 84.4 | 84.3 | 84.6 | 84.8 | 84.7 |
| Polyvinyl alcohol content | 21.8 | 21.1 | 21.5 | 21.6 | 21.2 | 21.3 |
| [mol %] | | | | | | |
| Polyvinyl acetate content | 1.1 | 1.1 | 0.9 | 0.7 | 0.8 | 0.7 |
| [mol %] | | | | | | |
| Butyral content [mol %] | 77.1 | 77.8 | 77.6 | 77.8 | 78.1 | 78.0 |
| Viscosity PVB 5% (mPa · s) | 120 | 120 | 79.8 | 90.9 | 103.7 | 120.5 |
| Film | | | | | | |
| Plasticiser | DINCH | DINCH | DINCH | DINCH | DINCH | DINCH |
| Plasticiser [w %] | 26.0 | 26 | 26.0 | 26.0 | 26.0 | 26.0 |
| Tg, Midpoint DIN [° C.] | — | — | 23.69 | — | — | — |
| Mw, PVB [g/mol] | 122300 | 122400 | 111450 | 127200 | 141850 | 159600 |
| MFR 100° C./21.6 kg | 172 | 180 | 340 | 227 | 189 | 105 |
| [mg/10 min.] | | | | | | |
| Electrical contact | 4.50E+13 | 7.5E+13 | 9.70E+13 | 3.70E+13 | 5.50E+13 | 4.60E+13 |
| resistance in Ohm * cm | | | | | | |
| Water content according | 1.69 | 1.64 | 1.62 | 1.63 | 1.72 | 1.67 |
| to Karl-Fischer method in | | | | | | |
| %/weight % | | | | | | |
| Slippage in mm | 1 | 0 | 4 | 1 | 1 | 0 |

TABLE 4

| | Example | | | | | |
|---|---|---|---|---|---|---|
| | B13 | B14 | B15 | B16 | B17 | B18 |
| PVB | | | | | | |
| Viscosity PVA 4% (mPa · s) | 30.75 | 30.75 | 27.06 | 27.06 | 27.06 | 27.06 |
| Precipitation phase [min] | 21 | 21 | 115 | 175 | 235 | 126 |
| Heating phase [min] | 200 | 200 | 200 | 200 | 200 | 200 |
| Polyvinyl alcohol content | 11.1 | 11.3 | 14.5 | 15.1 | 14.8 | 15.0 |
| [w %] | | | | | | |
| Polyvinyl acetate content | 9.0 | 8.8 | 1.0 | 0.9 | 0.9 | 1.0 |
| [w %] | | | | | | |
| Butyral content [w %] | 79.9 | 79.9 | 84.5 | 84.0 | 84.2 | 84.0 |
| Polyvinyl alcohol content | 17.0 | 17.3 | 21.5 | 22.3 | 22.0 | 22.2 |
| [mol %] | | | | | | |
| Polyvinyl acetate content | 7.1 | 6.9 | 0.7 | 0.7 | 0.7 | 0.8 |
| [mol %] | | | | | | |
| Butyral content [mol %] | 75.9 | 75.8 | 77.7 | 77.0 | 77.3 | 77.0 |
| Viscosity PVB 5% (mPa · s) | 111.6 | 152.1 | 83.6 | 87.8 | 88.3 | 90.4 |
| Film | | | | | | |
| Plasticiser | DINCH | DINCH | DINCH | DINCH | DINCH | DINCH |
| Plasticiser [w %] | 26 | 26 | 26.0 | 26 | 26 | 26 |
| Tg, Midpoint DIN [° C.] | — | — | 22.08 | — | — | — |
| Mw, PVB [g/mol] | 141800 | 172400 | 102525 | 103225 | 102075 | 116700 |
| MFR 100° C./21.6 kg | 221 | 103 | 156 | 131 | 116 | 253 |
| [mg/10 min.] | | | | | | |
| Electrical contact | 4.90E+13 | 5.60E+13 | 9.20E+13 | 1.2E+14 | 7.5E+13 | 4.10E+13 |
| resistance in Ohm * cm | | | | | | |
| Water content according to | 1.52 | 1.54 | 1.64 | 1.68 | 1.7 | 1.78 |
| Karl-Fischer method in | | | | | | |
| %/weight % | | | | | | |
| Slippage in mm | 3 | 0 | 1 | 0 | 0 | 2 |

TABLE 5

| | Example | | |
|---|---|---|---|
| | B19 | B20 | B21 |
| PVB | | | |
| Viscosity PVA 4% (mPa · s) | 27.06 | 30.75 | 30.75 |
| Precipitation phase [min] | 175 | 106 | 166 |
| Heating phase [min] | 200 | 200 | 200 |
| Polyvinyl alcohol content | 14.7 | 11.8 | 11.6 |
| [w %] | | | |
| Polyvinyl acetate content | 1.1 | 9.2 | 9.6 |
| [w %] | | | |
| Butyral content [w %] | 84.2 | 79.0 | 78.8 |
| Polyvinyl alcohol content | 21.8 | 18.0 | 17.8 |
| [mol %] | | | |
| Polyvinyl acetate content | 0.8 | 7.2 | 7.5 |
| [mol %] | | | |
| Butyral content [mol %] | 77.4 | 74.8 | 74.7 |
| Viscosity PVB 5% (mPa · s) | 102.6 | 131.6 | 124.2 |
| Film | | | |
| Plasticiser | DINCH | DINCH | DINCH |
| Plasticiser [w %] | 26 | 26 | 26 |
| Tg, Midpoint DIN [° C.] | — | — | — |
| Mw, PVB [g/mol] | 115400 | 160500 | 155400 |
| MFR 100° C./21.6 kg | 106 | 121 | 181 |
| [mg/10 min.] | | | |
| Electrical contact | 1.30E+13 | 8.90E+13 | 2.00E+14 |
| resistance in Ohm * cm | | | |
| Water content according to | 1.68 | 1.54 | 1.5 |
| Karl-Fischer method in | | | |
| %/weight % | | | |
| Slippage in mm | 0 | 0 | 1 |

Without further elaboration, it is believed that one skilled in the art can, using the preceding description, utilize the present invention to its fullest extent. The preceding preferred specific embodiments are, therefore, to be construed as merely illustrative, and not limitative of the remainder of the disclosure in any way whatsoever.

In the foregoing and in the examples, all temperatures are set forth uncorrected in degrees Celsius and, all parts and percentages are by weight, unless otherwise indicated.

The entire disclosures of all applications, patents and publications, cited herein and of corresponding EPO application No. 09162037.6, filed Jun. 5, 2009, are incorporated by reference herein.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

1. Photovoltaic module including a laminate consisting of
a) a transparent front cover
b) one or more photosensitive semiconductor layers
c) at least one film based on polyvinyl acetal and containing plasticiser, and
d) a rear cover,
characterized in that the polyvinyl acetal-based film c) containing plasticiser includes polyvinyl acetal having a polyvinyl alcohol content less than 18% by weight and a creep tendency less than 5 mm after 7 days at a temperature of 100° C., as determined on a laminate with a structure of 3 mm float glass/0.76 mm film c)/3 mm float glass.

2. The photovoltaic module as recited in claim 1, characterized in that the polyvinyl acetals have a Mw molecular weight or more than 110,000 g/mol.

3. The photovoltaic module as recited in claim 1, characterized in that the polyvinyl acetals have a solution viscosity of more than 80 mPas.

4. The photovoltaic module as recited in claim 1, characterized in that the polyvinyl acetals are crosslinked via carboxyl groups, due to polyaldehydes, glutardialdehyde or glyoxylic acid.

5. The photovoltaic module as recited in claim 1, characterized in that the polyvinyl acetals are produced by a process having the steps
preparation of an aqueous solution of polyvinyl alcohol and at least one aldehyde
addition of an acid, resulting in precipitation of the polyvinyl acetal at low temperature (precipitation phase)
heating the reagent mixture to an elevated temperature (heating phase),
wherein the precipitation phase lasts from 60 to 360 minutes.

6. The photovoltaic module as recited in claim 1, characterized in that the polyvinyl acetals are produced by a process having the steps
preparation of an aqueous solution of polyvinyl alcohol and acid
addition of at least one aldehyde, resulting in precipitation of the polyvinyl acetal at low temperature (precipitation phase)
heating the reagent mixture to an elevated temperature (heating phase),
wherein the precipitation phase lasts from 60 to 360 minutes.

7. The photovoltaic module as recited in claim 1, characterized in that the polyvinyl acetal has a polyvinyl acetate proportion of less than 14% by weight.

8. The photovoltaic module as recited in claim 1, characterized in that the plasticiser-containing, polyvinyl acetal-based films c) have a plasticiser content of 18 to 32% by weight.

9. The photovoltaic module as recited in claim 1, characterized in that one or more compounds whose polarity, as expressed in the formula 100×O/(C+H), is less than/equal to 9.4, where O, C and H stand for the number of oxygen, carbon, and hydrogen atoms in the respective molecule are used as plasticisers.

10. The photovoltaic module as recited in claim 1, characterized in that one or more compounds from the group Di-2-ethylhexyl sebacate, Di-2-ethylhexyl adipate, Di-2-ethylhexyl phthalate, Dihexyl adipate, Dibutyl sebacate, Di-2-butoxyethyl sebacate, Triethylene glycol-bis-2-ethylhexanoate, and 1,2 Cyclohexane dicarboxylic acid diisononyl ester are used as plasticisers.

11. The photovoltaic module as recited in claim 1, characterized in that the film based on plasticiser-containing polyvinyl acetal contains less than 50 ppm metal ions.

12. The photovoltaic module as recited in claim 1, characterized in that the film based on plasticiser-containing polyvinyl acetal contains 0.001 to 5% by weight SiO₂.

13. The photovoltaic module as recited in claim 1, characterized in that polyvinylbutyral is used as the polyvinyl acetal.

14. Use of films containing plasticiser and based on polyvinyl acetal with a polyvinyl alcohol content in the polyvinyl acetal of less than 18% by weight and a creep tendency of less than 5 mm after 7 days at a temperature of 100° C., as determined on a laminate having a construction of 3 mm float glass/0.76 mm film c)/3 mm float glass, to produce photovoltaic modules.
